(19) United States
(12) Patent Application Publication
(10) Pub. No.: US 2024/0321820 A1
(43) Pub. Date: Sep. 26, 2024

(54) BONDING METHOD

(71) Applicant: COMMISSARIAT A L'ENERGIE ATOMIQUE ET AUX ENERGIES ALTERNATIVES, Paris (FR)

(72) Inventor: Mark SCANNELL, GRENOBLE Cedex (FR)

(21) Appl. No.: 18/610,960

(22) Filed: Mar. 20, 2024

(30) Foreign Application Priority Data
Mar. 21, 2023 (FR) 2302624

(51) Int. Cl. H01L 23/00

(52) U.S. Cl. CPC H01L 24/80; H01L 24/05; H01L 24/08; H01L 2224/05647; H01L 2224/08145; H01L 2224/80052; H01L 2224/80357; H01L 2224/80379; H01L 2224/80895; H01L 2224/80896; H01L 2924/05042; H01L 2924/0534; H01L 2924/05342; H01L 2924/0535; H01L 2924/05432; H01L 2924/0544

(57) ABSTRACT

A bonding method including the steps of: providing a first substrate comprising a first face comprising a first dielectric material and first metal pads, providing a second substrate comprising a first face comprising a second dielectric material, second metal pads, and a metal portion, placing the first face of the first substrate (100) in contact with the first face of the second substrate, so that, in a first zone the first metal pads are disposed facing the second metal pads and, in a second zone, the first metal pads are disposed facing the second dielectric material and the metal portion is disposed facing the first dielectric material, and performing a heat treatment.

### CROSS-REFERENCE TO RELATED APPLICATIONS

This application claims priority from French Patent Application No. FR2302624 filed on Mar. 21, 2023. The content of this application is incorporated herein by reference in its entirety.

### TECHNICAL FIELD

The present invention relates to the general field of bonding methods, and in particular hybrid bonding methods.

The invention relates to a bonding method.

The invention also relates to a structure obtained by a bonding method.

The invention has applications in many industrial fields, and particularly for the manufacturing of micro- and nano-electronic components.

The invention is particularly interesting since it makes it possible to facilitate contact pick-ups on assemblies obtained with a hybrid bonding method.

### PRIOR ART

Currently, to create vertically connected and stacked integrated circuits, hybrid bonding is implemented.

As shown in FIGS. 1A and 1B, this type of bonding consists in bonding together two substrates 10, 20 and more particularly two surfaces 11, 21, comprising metal pads 13 and an insulating material 12. Under each surface, the metal pads 13 are connected to the transistors. By assembling the substrates 10, 20, the metal zones come into contact and the transistors are connected on either side of the interface.

This type of bonding is particularly interesting because it makes it possible to achieve an interconnection pitch in the order of the micrometre and high interconnection densities.

However, it requires the use of through-silicon vias 30 (TSV) because the electrical contacts are inaccessible after the bonding (FIGS. 1A and 1B).

Yet, the manufacturing of TSV requires many steps, which considerably increases the manufacturing costs and the number of steps of the method (implementing TSV, treating the rear face, revealing TSV, rear face redistribution layer (RDL)).

### DISCLOSURE OF THE INVENTION

One aim of the present invention is to propose a bonding method remedying the drawbacks of the prior art and making it possible, particularly, to make the electrical contacts easily accessible.

For this, the present invention proposes a bonding method comprising the following steps of:
providing a first substrate comprising a first face and a second face, the first face of the first substrate comprising a first dielectric material and metal pads,
providing a second substrate comprising a first face and a second face, the first face of the second substrate comprising a second dielectric material, metal pads, and a metal portion,
preferably, performing a treatment of the first face of the first substrate and of the second face of the second substrate (for example, a polishing and/or plasma activation treatment),
placing the first face of the first substrate in contact with the first face of the second substrate,
performing a heat treatment to assemble the first substrate with the second substrate.

The metal pads of the first substrate, the metal pads of the second substrate and the metal portion of the second substrate are disposed so that, when placing the first face of the first substrate in contact with the first face of the second substrate two zones are formed:
in a first zone the metal pads of the first substrate are disposed facing the metal pads of the second substrate, and
in a second zone the metal pads of the first substrate are disposed facing the second dielectric material and the metal portion of the second substrate is disposed facing the first dielectric material.

Advantageously, the method further comprises a subsequent removal step during which the section of the second substrate disposed at the second zone is removed.

The invention differs fundamentally from the prior art by the particular positioning of the metal pads of the two wafers as well as the metal portion of the second substrate. Thus, at the second zone, there are only metal/dielectric interfaces. There are no metal/metal interfaces or dielectric/dielectric interfaces.

In a conventional layout, the metal pads would be opposite other metal pads (metal/metal bonding) and the dielectric material opposite the dielectric material (dielectric/dielectric bonding).

While the dielectric/dielectric and metal/metal bonding forces are very strong, the dielectric material bonds poorly to metal. For example, the bonding force between SiO2 and Cu is very low or even negligible, pre- and post-annealing.

By way of illustration, for example, in “solid wafer” format, the metal/metal bonding forces are more than 3 J/m² for Cu—Cu, after annealing at 100° C., and the bonding forces for SiO2-SiO2 are approximately 2 J/m² after annealing at 400° C. For additional wafers comprising an SiO2 dielectric surface and Cu pads in view of hybrid bonding, the bonding forces may reach up to approximately 6.5 J/m² after annealing at 400° C.

With the layout according to the invention, it is possible to easily leave a section of the upper substrate (i.e. the second substrate) free after hybrid bonding and cutting to reveal the electrical pads.

Indeed, as the first zone has strong bonding energies (on the one hand, metal/metal and, on the other hand, dielectric/dielectric) and as the second zone has negligible or even zero bonding energies (metal/dielectric), separating the section of the second substrate at the second zone is relatively simple to implement.

Thus, during the removal step, the section of the second substrate at the first zone remains bonded to the first substrate and the section of the second substrate at the second zone detaches from the first substrate.

Implementing a method that eliminates (and therefore “wastes”) a significant substrate surface at first glance seems disadvantageous. However, in this method the added value of the bonded section justifies the sacrifice of the removed section and/or the discarded section may be fairly inexpensive (for example, it may concern a passive device).

With such a method, it is not systematically necessary to manufacture TSV, or RDL.

Advantageously, the first dielectric material is an oxide or a nitride, preferably a silicon oxide and/or the second dielectric material is an oxide or a nitride, preferably a silicon oxide.

Advantageously, the metal pads of the first substrate, the metal pads of the second substrate and/or the metal portion of the second substrate are made of copper.

Advantageously, the removal step is carried-out according to the following sub-steps of:
cutting the second substrate, for example by saw, laser or chemical etching, the cutting being carried-out so as to be able to leave the section of the second substrate disposed at the second area free,
ii) removing the section of the second substrate disposed at the second zone.

Advantageously, sub-step ii) is carried-out by bonding an adhesive element on the second substrate.

According to a first advantageous alternative embodiment, sub-step ii) is carried-out by bonding an adhesive element on the section of the second substrate disposed at the second zone.

According to another advantageous alternative embodiment, sub-step ii) is carried-out by bonding an adhesive element on the entire second substrate. The “unbonded” section (i.e. section of the second substrate disposed at the second zone) will be removed with the adhesive element.

Advantageously, after the heat treatment, the method includes a step during which the second substrate is thinned from the second face. This step is, advantageously, carried-out before the removal step and/or before the cutting step.

Advantageously, the metal pads of the first substrate and/or the metal pads of the second substrate have a surface, preferably square or rectangular, the largest dimension of the surface being between 1 μm and 1 mm. The surface of the metal pads is, for example, between 3 μm² and 1 mm².

The invention also relates to a device comprising a first substrate assembled with a second substrate:
the first substrate comprising a first face and a second face, the first face of the first substrate comprising a first dielectric material and metal pads, preferably made of copper,
the second substrate comprising a first face and a second face, the first face of the second substrate comprising a second dielectric material and metal pads, preferably made of copper, and a metal portion, preferably made of copper,
the first face of the first substrate being disposed facing the first face of the second substrate.

In a first zone, the metal pads of the first substrate are disposed facing the metal pads of the second substrate. In a second zone, the metal pads of the first substrate are disposed facing the second dielectric material and the metal portion of the second substrate is disposed facing the first dielectric material.

Advantageously, the first dielectric material is an oxide or a nitride, preferably a silicon oxide and/or the second dielectric material is an oxide or a nitride, preferably a silicon oxide.

Other features and advantages of the invention will become apparent from the following additional description.

It goes without saying that this additional description is only given by way of illustration of the subject matter of the invention and shall under no circumstances be interpreted as a limitation of this subject matter.

### BRIEF DESCRIPTION OF THE DRAWINGS

The present invention will be better understood upon reading the description of examples of embodiment given, purely by way of indicative and non-limiting example, while referring to the appended drawings wherein:

FIGS. 1A and 1B previously described, show, schematically, various steps of a bonding method according to the prior art.

FIGS. 2A, 2B, 2C, 2D and 2E show, schematically, various steps of a bonding method according to a particular embodiment of the invention.

FIG. 3 shows, schematically, in three dimensions, a step of a bonding method according to another particular embodiment of the invention.

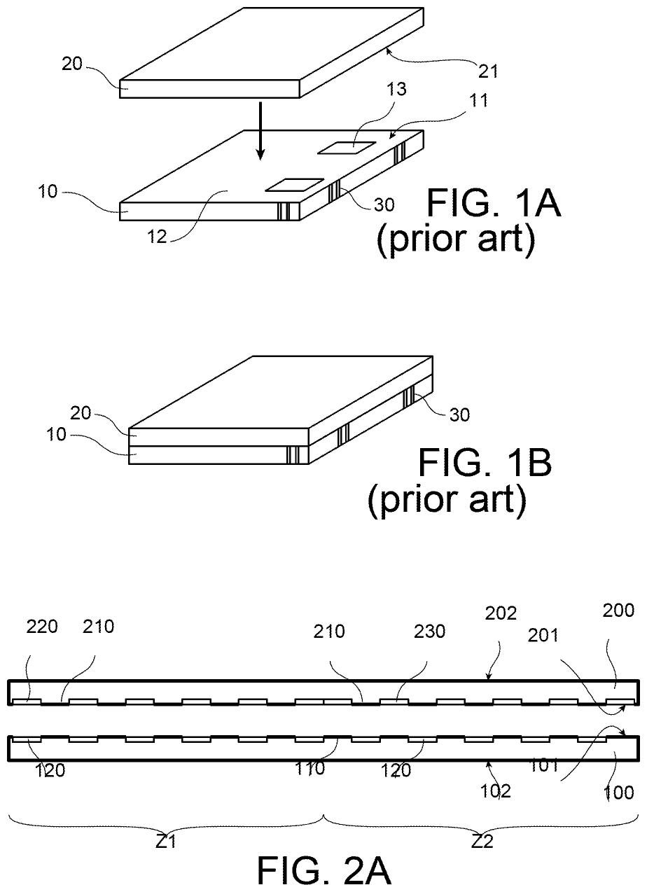

The various portions represented in the figures are not necessarily according to a uniform scale, in order to make the figures more readable.

The various options (alternative embodiments and embodiments) should be understood as not being mutually exclusive and can be combined with one another.

Furthermore, in the description hereinafter, terms that depend on the orientation, such as “above”, “below”, etc. of a structure are applied by considering that the structure is oriented in the manner illustrated in the figures.

### DETAILED DISCLOSURE OF PARTICULAR EMBODIMENTS

Although in no way limiting, the invention particularly applies to the field of microelectronics.

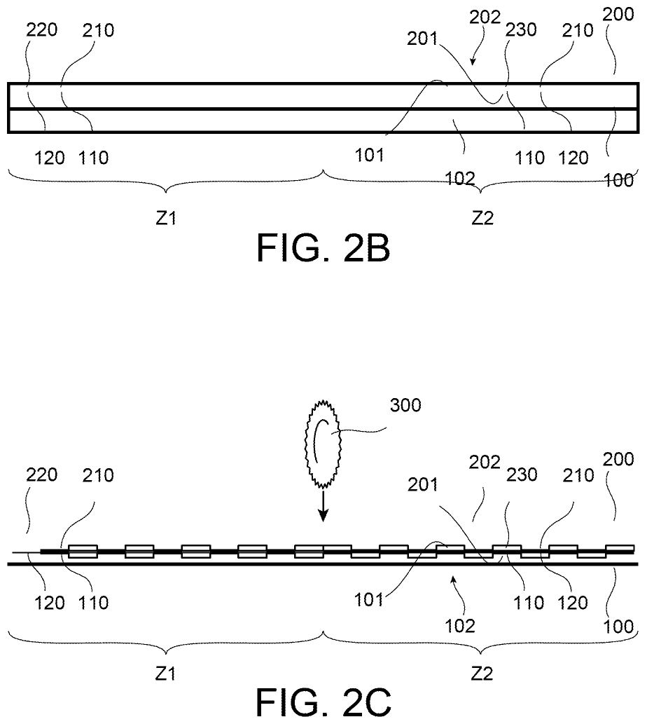

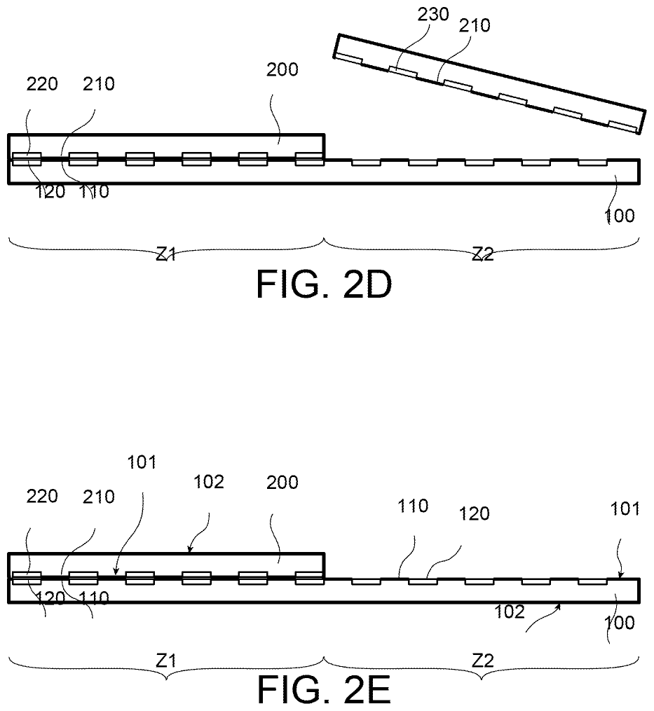

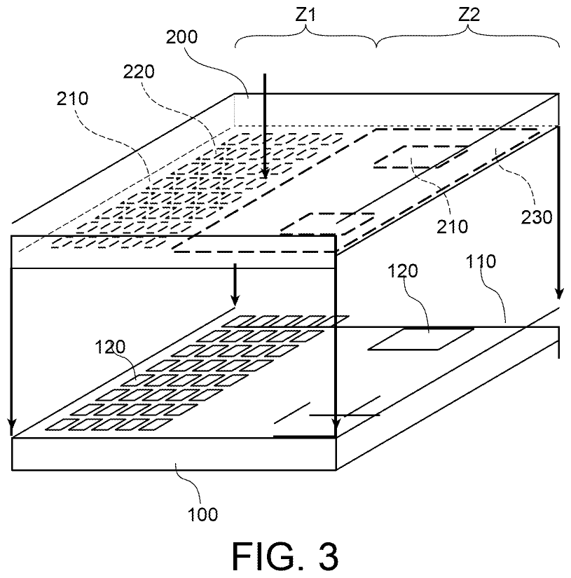

The bonding method comprises the following steps (FIGS. 2A to 2E and FIG. 3) of:
providing a first substrate 100 comprising a first face 101 and a second face 102, the first face 101 of the first substrate 100 comprising a first dielectric material 110 and metal pads 120,
b) providing a second substrate 200 comprising a first face 201 and a second face 202, the first face 201 of the second substrate 200 comprising a second dielectric material 210, metal pads 220 and a metal portion 230,
b′) preferably, performing a treatment of the two faces intended to be placed in contact (for example by polishing and/or plasma activation) for making them mutually directly bondable, due to Van der Waals forces,
c) placing the first face 101 of the first substrate 100 in contact with the first face 201 of the second substrate 200; placing the two substrates in contact leading to the formation of two zones:
in a first zone Z1, the metal pads 120 of the first substrate 100 are disposed facing the metal pads 220 of the second substrate 200,
in a second zone Z2, the metal pads 120 of the first substrate 100 are disposed facing the second dielectric material 210 and the metal portion 230 of the second substrate 200 is disposed facing the first dielectric material 110,
d) performing a heat treatment to assemble the first substrate 100 with the second substrate 200; the heat treatment making it possible to increase the adhesion forces between the surfaces and to reduce the resistivity between the metal pads by recrystallisation,
e) preferably, removing a section of the second substrate 200 to release at least a portion of the metal pads 120 of the first substrate 100.

The substrates 100, 200 provided in step a) and in step b) each comprise two main faces: a first face 101, 201 and a second face 102, 202. These faces are parallel or substantially parallel to one another.

The substrates 100, 200 are, for example, wafers.

The first face 101, 201 of each substrate 100, 200 is, advantageously, flat in order to increase the direct dielectric/dielectric and metal/metal bonds (Van der Waals forces).

The first face 101, 201 of each substrate 100, 200 comprises a dielectric material 110, 210 and metal pads 120, 220.

The metal pads 120, 220 may cover the dielectric material 110, 210. The metal pads 120, 220 may penetrate the dielectric material 110, 210. The metal pads 120, 220 may pass through the thickness of the dielectric material 110, 210.

The metal pads 120, 220 of the same substrate 100, 200 are electrically insulated from one another by the dielectric material 110, 210.

The metal pads 120, 220 may be evenly spaced.

The surface of the pads 120, 220 may be of any shape. It is, preferably, square or rectangular. The largest dimension of the surface of the pads 120, 220 is, for example, between 1 μm and 3 mm, preferably between 1 μm and 1 mm.

For example, for a square the largest dimension is the side. For a rectangle, the largest dimension is the length.

At the first zone, the metal pads 120 of the first substrate 100 and the metal pads 220 of the second substrate 200 are identical and disposed in the same manner on the substrates, so that, during the assembly, they are facing one another.

As regards the first substrate 100, the pads of the first zone Z1 may be identical to or different from the pads of the second zone Z2.

When the pads are different:
the largest dimension of the surface of the pads 120 of the first zone Z1 is, preferably, between 1 μm and 15 μm, even more preferably between 3 and 10 μm; these pads are so-called intersection pads between the chips,
the largest dimension of the surface of the pads 120 of the second zone Z2 is, preferably, between 20 μm and 3 mm, preferably between 50 μm and 1 mm; these pads are used to electrically connect the device to an external element to the device.

Preferably, the pads of the first zone Z1 are identical to the pads of the second zone Z2. For example, the largest dimension of the surface of the pads 120 of the first zone Z1 and the largest dimension of the surface of the pads of the second zone Z2 are between 1 μm and 3 mm, preferably between 1 μm and 1 mm, even more preferably between 1 μm and 15 μm, and even more preferably between 3 and 10 μm.

The metal pads 120 of the first substrate 100 and the metal pads 220 of the second substrate 200 may be made of the same material or made of different materials. The metal pads 120, 220 are, for example, made of Cu, W, Al, Ti, Ta, Ge, Ga or one of their alloys. Preferably, the metal pads 120, 220 are made of copper.

At the second zone Z2, the second substrate 200 further comprises a metal portion 230. The metal portion 230 has a shape complementary to the metal pads 120 of the first substrate 100 disposed at the second zone Z2. For example, it concerns a metal layer comprising openings having the shape of the pads 120 of the first substrate of the second zone Z2, and positioned such that, when placing the substrates 100, 200 in contact, the openings are facing these pads (FIG. 3).

The metal portion 230 is, for example, made of Cu, W, Al, Ti, Ta, Ge, Ga or one of their alloys. Preferably, it is made of copper.

The first dielectric material 110 and the second dielectric material 210 may be identical or different.

Preferably, the first dielectric material 110 and the second dielectric material 210 are oxides. Preferably, it concerns silicon oxide. It may also concern germanium dioxide or an oxide of SiGe, or also of Ta₂O₅, Al₂O₃, ZrO₂ or of HfO₂.

According to another preferred embodiment, the first dielectric material 110 and the second dielectric material 210 are nitrides. For example, it may concern an SiNₓ nitride.

The dielectric material 110, 210 of each substrate 100, 200 is covered locally by metal pads 120, 220.

Between step b) and step c), a polishing step is, advantageously, carried-out to obtain a first substrate 100 and/or a second substrate 200 having flat surfaces. For example, this step may be carried-out by Chemical Mechanical Polishing (CMP).

The metal pads 120 of the first substrate 100, the metal pads 220 of the second substrate 200 and the metal portion 230 of the second substrate are disposed so that, during step c), two zones are formed.

In a first zone (noted Z1 in the figures), the metal pads 120 of the first substrate 100 are disposed facing the metal pads 220 of the second substrate 200. The first dielectric material 110 is therefore disposed facing the second dielectric material 210. In the zone Z1, there are two types of bonding, metal/metal, on the one hand, and, on the other hand, dielectric/dielectric.

In a second zone (noted Z2 in the figures), the metal pads 120 of the first substrate 100 are disposed facing the second dielectric material 210 and the metal portion 230 of the second substrate 200 is disposed facing the first dielectric material 110. In the zone Z2, there is only one type of bonding: the metal/dielectric bonding.

At this second zone Z2, a covering tolerance between the first dielectric material 110 and the metal portion 230 of the second substrate 200 and/or between the second dielectric material 210 and the pads 120 of the first substrate 100 may be accepted. The tolerance is, preferably, less than 5%, more preferably less than 2%, even more preferably less than 1%. Less than 5% means that less than 5% of the surface of each metal pad is covered with a dielectric material. For example, the offset may be between 2 and 20 nm. In other words, the first dielectric material 110 and the metal portion 230 of the second substrate 200 and/or the second dielectric material 210 and the pads 120 of the first substrate 100 may be covered over a covering length between 2 nm and 20 nm.

The first zone Z1 and the second zone Z2 may each represent approximately 50% of the surface of the substrates. The proportion of each zone may be adapted depending on the final device desired. For example, Z1 may represent 80% of the surface of the substrates and Z2 20% of the surface of the substrates.

During step d), the heat treatment is, for example, performed at a temperature between 200° C. and 400° C. This step increases the adhesion energies at the first zone Z1.

Even after step d), the adhesion energies at the second zone Z2 remain low or even negligible.

The difference in adhesion energy between the first zone Z1 and the second zone Z2 is greater after annealing than before annealing.

After step d), the section of the substrates 100, 200 at the second zone Z2 (so-called unbonded zone) is mechanically maintained by the section of the substrates 100, 200 at the first zone Z1 (so-called bonded zone).

Advantageously, after step d), the method further comprises a step e) during which the section of the second substrate 200 disposed at the second zone Z2 is removed.

The removal step is carried-out according to the following sub-steps of:
cutting the second substrate 200, for example, by saw, laser or chemical etching, the cutting being carried-out so as to be able to leave the section of the second substrate 200 at the second zone Z2 free,
ii) removing the section of the second substrate 200 at the second zone Z2.

During step i), cutting is carried-out at the border of the first zone Z1 and of the second zone Z2 in order to separate the second substrate 200 into two sections.

Step i) can be carried-out by a conventional sawing technique. A saw 300 is, for example, shown in FIG. 2C. Step i) can be carried-out by other techniques, for example by a step of laser etching and/or by chemical etching. Sub-step ii) leads, advantageously, to the formation of a trench going from the first face 201 to the second face 202 of the second substrate 200.

Sub-step ii) can be carried-out by bonding an adhesive element on the section of the second substrate 200 positioned at the second zone Z2.

Alternatively, sub-step ii) can be carried-out by bonding an adhesive element on the entire second substrate 200. When the adhesive element is removed, the unbonded zones will leave with the adhesive element, the bonded zones will not move.

It may also be possible to remove the unbonded section of the second substrate 200 by a hydraulic means (projection of water and/or of air), by chemical removal (acids), by thermal expansion (including local thermal expansion applied by laser), by thermal contraction (cold treatment), or by a combination of these possibilities.

Between step d) and step e), the method may include a step during which the second substrate 200 is thinned from the second face 202.

Thinning may be obtained by conventional grinding, by chemical etching, by reactive ions or by a combination of these techniques.

Thus, after step d), a device is obtained comprising a first substrate 100 assembled with a second substrate 200:
the first substrate 100 comprising a first face 101 and a second face 102, the first face 101 of the first substrate 100 comprising a first dielectric material 110 and metal pads 120, preferably made of copper,
the second substrate 200 comprising a first face 201 and a second face 202, the first face 201 of the second substrate 200 comprising a second dielectric material 210, metal pads 220, preferably made of copper, and a metal portion 230, preferably made of copper.

The first face 101 of the first substrate 100 is disposed facing the first face 201 of the second substrate 200.

In a first zone Z1, the metal pads 120 of the first substrate 100 are disposed facing the metal pads 220 of the second substrate 200.

In a second zone Z2, the metal pads 120 of the first substrate 100 are disposed facing the second dielectric material 210 and the metal portion 230 of the second substrate 200 is disposed facing the first dielectric material 110.

After step e), a device is obtained comprising the first substrate 100 (so-called base substrate) locally covered by the second substrate 200 at the first zone Z1. At the second zone Z2, the metal pads 120 of the first substrate 100 are exposed and therefore accessible for performing a contact pick-up.

The method may further comprise one or more of the following steps of: cleaning the pads (if necessary), cutting and packaging.

1. A bonding method comprising the steps of:
providing a first substrate comprising a first face and a second face, the first face of the first substrate comprising a first dielectric material and first metal pads;
providing a second substrate comprising a first face and a second face, the first face of the second substrate comprising a second dielectric material, second metal pads and a metal portion;
placing the first face of the first substrate in contact with the first face of the second substrate;
performing a heat treatment to assemble the first substrate with the second substrate,
wherein the first metal pads, the second metal pads and the metal portion are disposed so that, when placing the first face of the first substrate in contact with the first face of the second substrate, in a first zone the first metal pads are disposed facing the second metal pads) of the second substrate and in a second zone the first metal pads are disposed facing the second dielectric material and the metal portion is disposed facing the first dielectric material; and
removing the section of the second substrate, disposed at the second zone.

2. The method according to claim 1, wherein the first dielectric material is an oxide or a nitride and/or the second dielectric material is an oxide or a nitride.

3. The method according to claim 2, wherein the first dielectric material is a silicon oxide and/or the second dielectric material is a silicon oxide.

4. The method according to claim 1, wherein the first metal pads, the second metal pads and/or the metal portion are made of copper.

5. The method according to claim 1, wherein the removing step is carried-out according to the sub-steps of:
i) cutting the second substrate so as to leave the section of the second substrate disposed at the second zone free,
ii) removing the section of the second substrate at the second zone.

6. The method according to claim 5, wherein the cutting is done by laser, saw or chemical etching.

7. The method according to claim 5, wherein sub-step ii) is carried-out by bonding an adhesive element on the second substrate.

8. The method according to claim 1, wherein after the heat treatment, the method further includes a step of thinning the second substrate from the second face.

9. The method according to claim 1, wherein the first metal pads and/or the second metal pads have a surface with a largest dimension between 1 μm and 1 mm.

10. The method according to claim 9, wherein the surface is substantially rectangular or substantially square.

11. A device comprising a first substrate assembled with a second substrate:
the first substrate comprising a first face and a second face, the first face of the first substrate comprising a first dielectric material and first metal pads),
the second substrate comprising a first face and a second face, the first face of the second substrate comprising a second dielectric material, second metal pads, and a metal portion,
the first face of the first substrate being disposed facing the first face of the second substrate, wherein, in a first zone, the first metal pads are disposed facing the second metal pads and, in a second zone, the first metal pads are disposed facing the second dielectric material and the metal portion is disposed facing the first dielectric material.

12. The device according to claim 11, wherein the first metal pads, the second metal pads and/or the metal portion are made of copper.

13. The device according to claim 11, wherein the first dielectric material is an oxide or a nitride and/or the second dielectric material is an oxide or a nitride.

14. The device according to claim 13, wherein the first dielectric material is a silicon oxide and/or the second dielectric material is a silicon oxide.
